(19) United States
(12) Patent Application Publication
(10) Pub. No.: US 2013/0267097 A1
(43) Pub. Date: Oct. 10, 2013

(54) METHOD AND APPARATUS FOR FORMING FEATURES WITH PLASMA PRE-ETCH TREATMENT ON PHOTORESIST

(71) Applicants: Ratndeep SRIVASTAVA, Sunnyvale, CA (US); Qinghua ZHONG, Fremont, CA (US); Tae Won KIM, Dublin, CA (US); Gowri KAMARTHY, Pleasanton, CA (US)

(72) Inventors: Ratndeep SRIVASTAVA, Sunnyvale, CA (US); Qinghua ZHONG, Fremont, CA (US); Tae Won KIM, Dublin, CA (US); Gowri KAMARTHY, Pleasanton, CA (US)

(73) Assignee: LAM RESEARCH CORPORATION, Fremont, CA (US)

(21) Appl. No.: 13/440,365

(22) Filed: Apr. 5, 2012

(51) Int. Cl. H01L 21/3065; C23F 1/08

(52) U.S. Cl. 438/710; 156/345.24; 257/E21.218

(57) ABSTRACT

A method for forming features through a photoresist mask into an underlying layer is provided. The photoresist mask has patterned mask features. The photoresist mask has patterned mask features. A treatment gas containing H₂ and N₂ is provided. A plasma is generated from the treatment gas, and the photoresist mask is exposed to the plasma. The treatment gas is stopped, and then the features are etched into the underlying layer through the plasma-treated photoresist mask.

### BACKGROUND OF THE INVENTION

The present invention relates to reducing line width roughness (LWR) of a photoresist mask feature, as well as controlling critical dimension (CD) of the mask feature. More specifically, the present invention relates to a pre-etch plasma treatment of a patterned photoresist mask through which a feature is formed in an underlying layer.

During semiconductor wafer processing, features of the semiconductor device are defined in the wafer using well-known patterning and etching processes. In these processes, a photoresist (PR) material may be deposited on the wafer and then is exposed to light filtered by a reticle. The reticle may be a transparent plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material, resulting in a patterned photoresist mask. In the case of positive photoresist materials, the exposed regions are removed, and in the case of negative photoresist materials, the unexposed regions are removed. Thereafter, the wafer is etched to remove the underlying material from the areas that are no longer protected by the patterned photoresist mask, and thereby produce the desired features in the wafer.

As the critical dimensions (CDs) of semiconductor integrated circuitry features shrinks below 45 nm, the control of photoresist mask layers for line and space features with conventional photolithography process is reaching its limits Poor and distorted line edges, as well as incompletely developed residue of photoresist layer will cause significant roughness at the edges of line and space features causing line edge roughness (LER) and variation in the CD of the line and space features defined as 6 (standard deviation) of CD and is defined in nm, i.e., line width roughness (LWR). This non-uniform edge pattern will be transferred and/or amplified during multiple etch process steps that are required for semiconductor device fabrication, causing degradation of device performance and yield loss.

The ideal feature has an edge that is “straight like a ruler” as shown in FIG. 1A, when viewed from top down. However, for various reasons as described above, the actual line feature may appear jagged and have line width roughness (LWR) caused by rough sidewall of the features. The LWR includes a low-frequency roughness, such as a wiggling (as shown in FIG. 1B), and a high-frequency roughness such as an irregular edge surface (as shown in FIG. 1C). In reality, the LWR is a combination of the high-frequency LWR and the low-frequency LWR. The LWR is a measure of how smooth the edge of a linear feature is when viewed from the top down. Features with high LWR are generally very undesirable because the CD measured along the line feature would vary from position to position, rendering operation of the resulting device unreliable.

### SUMMARY OF THE INVENTION

To achieve the foregoing and in accordance with the purpose of the present invention, a method for forming features through a photoresist mask into an underlying layer is provided. The photoresist mask has patterned mask features. A treatment gas containing H₂ and N₂ is provided. A plasma is generated from the treatment gas, and the photoresist mask is exposed to the plasma. The treatment gas is stopped, and then the features are etched into the underlying layer through the plasma-treated photoresist mask.

The mask features may include a line-space pattern, and the method includes controlling a flow ratio of N₂ with respect to H₂ in a treatment gas such that the exposing reduces line width roughness (LWR) of the mask features. The flow ratio of H₂ and N₂ (H₂:N₂) may be between 2:1 and 10:1. The exposing may allow the photoresist mask to reflow with reduction in height of the mask features, and reduces line width roughness (LWR) of the mask features

In accordance with one aspect of the invention, the treatment gas further contains hydrofluorocarbon. The hydrofluorocarbon may be CH₃F. The method may further include controlling a flow ratio of CH₃F with respect to H₂ in the treatment gas such that the exposing reduces a space critical dimension (CD) of the mask features. The flow ratio of H₂ and hydrofluorocarbon (H₂:CH₃F) may be between 10:1 and 100:1. The exposing may form C—N based depositions on sidewalls of the mask features. The exposing may harden the photoresist mask so as to increase the mask selectivity to the underlying layer during the forming features.

In accordance with another aspect of the invention, a method forming features through a photoresist mask into an underlying layer is provided, where the photoresist mask includes patterned mask features having a line width roughness (LWR) and a space critical dimension (CD). A treatment gas containing H₂, N₂, and CH₃F is provided. A plasma is generated from the treatment gas and the photoresist mask is exposed to the plasma, wherein exposing the photoresist mask to the plasma reduces both of the LWR and the space CD of the mask features. The treatment gas is stopped. The features are etched into the underlying layer through the plasma-treated photoresist mask.

The exposing allows the photoresist mask to reflow so as to reduce line width roughness (LWR) and a height of the mask features, while forming C—N based depositions on sidewalls of the mask features. The exposing may also increase selectivity to the underlying layer with respect to the photoresist mask during the forming features.

In accordance with yet another aspect of the invention, an apparatus for forming features through a patterned photoresist mask into an underlying layer is provided. The apparatus comprises a plasma processing chamber. The plasma processing chamber includes a chamber wall forming a plasma processing chamber enclosure, a chuck for supporting and chucking a substrate within the plasma processing chamber enclosure, a pressure regulator for regulating the pressure in the plasma processing chamber enclosure, at least one electrode or coil for providing power to the plasma processing chamber enclosure for sustaining a plasma, a gas inlet for providing gas into the plasma processing chamber enclosure, and a gas outlet for exhausting gas from the plasma processing chamber enclosure. The apparatus further comprises a gas source in fluid connection with the gas inlet. The gas source includes a treatment gas source, including an H₂ gas source, an N₂ source, and an optional hydrofluorocarbon gas source, and a feature-forming gas source. The apparatus further comprises a controller controllably connected to the gas source, the chuck, and the at least one electrode or coil. The controller includes at least one processor, and non-transient computer readable media. The computer readable media includes computer readable code for treating the photoresist mask disposed over the underlying layer. The computer readable code of treating the photoresist includes computer readable code providing a treatment gas containing H₂, N₂, and optional hydrofluorocarbon, computer readable code for forming a plasma from the treatment gas, computer readable code for exposing the photoresist mask to the plasma, wherein the exposing reduces both of line width roughness (LWR) and critical dimension (CD) of the mask features, and computer readable code for stopping the treatment gas. The computer readable media further includes computer readable code for forming the features into the underlying layer through the plasma-treated photoresist mask.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIGS. 1A-C are schematic diagrams for explaining line width roughness.

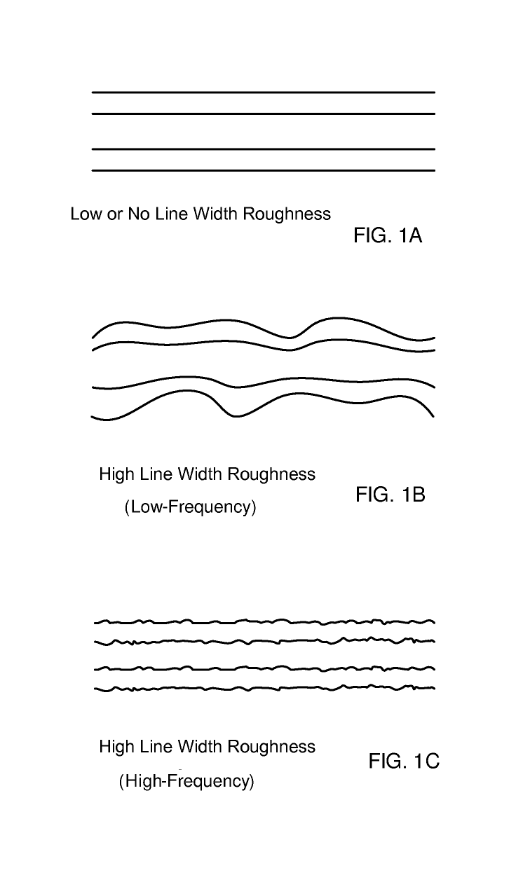

FIG. 2 is a diagram illustrating a schematic cross-sectional view of a stack of layers formed on a substrate, including a patterned photoresist mask having mask features and underlying layers, processed in accordance with embodiments of the present invention.

FIG. 3 is a process flow chart of a pre-etch plasma treatment in accordance with an embodiment of the invention.

FIGS. 4A and 4B schematically illustrate a cross-sectional view of a photoresist feature before and after the pre-etch plasma treatment, respectively, in accordance with one embodiment of the present invention.

FIG. 5 is a process flow chart of a pre-etch plasma treatment in accordance with another embodiment of the invention.

FIGS. 6A and 6B schematically illustrate a cross-sectional view of a photoresist feature before and after the pre-etch plasma treatment, respectively, in accordance with another embodiment of the present invention.

FIGS. 7A and 7B schematically illustrate a cross-sectional view of a photoresist feature before and after a pre-etch plasma treatment using H₂ and CH₃F, respectively, for comparison with the embodiments of the present invention.

FIG. 8 is a diagram illustrating a schematic view of a plasma processing chamber that may be used for the pre-etch plasma treatment in accordance with embodiments of the present invention.

FIG. 9 schematically illustrates a computer system, which is suitable for implementing a controller used in embodiments of the present invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

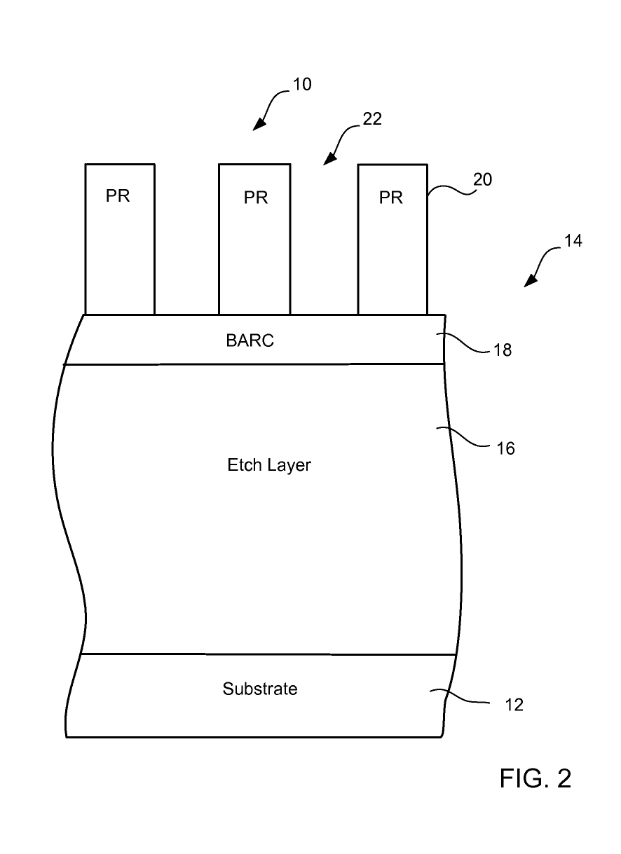

To facilitate understanding, FIG. 2 is a schematic cross-sectional view of an example of a wafer stack 10 having a patterned photoresist (PR) mask through which features are formed into an underlying layer, in accordance with embodiments of the present invention. The wafer stack 10 may include a substrate 12 and a stack of layers 14 formed on the substrate 12. As shown in FIG. 2, the underlying layer 18 may include a bottom antireflective coating (BARC) layer below the patterned photoresist (PR) mask 20, and an etch layer 16 disposed below the BARC layer. The underlying layer 18 below the patterned PR mask 20 may be a hard mask layer. The BARC layer and/or hard mask layer may be organic or inorganic. The etch layer 16 may be a conductive layer or dielectric layer. In this example, the PR mask 20 is of a 193 nm or higher generation photoresist material, and has mask features 22 that form a line-space pattern including a plurality of lines and spaces there between. The PR mask 20 may have a CD about 45 nm or less. In this line-space pattern example, the CD is a space CD between adjacent lines. In some application, the PR mask 20 may be required to have a CD of 32 nm, or 20 nm or even less. The PR mask is also required to have improved (i.e, small) line width roughness (LWR). The LWR may be defined as a standard deviation of the average line width of the mask feature.

However, the present invention is not limited to a specific stack of layers on the substrate, but is applicable to any patterned photoresist mask used as an etch mask for etching the underlying layers. It should also be noted that the present invention is applicable for both of the front end of line (FEOL) and back end of line (BEOL) processes.

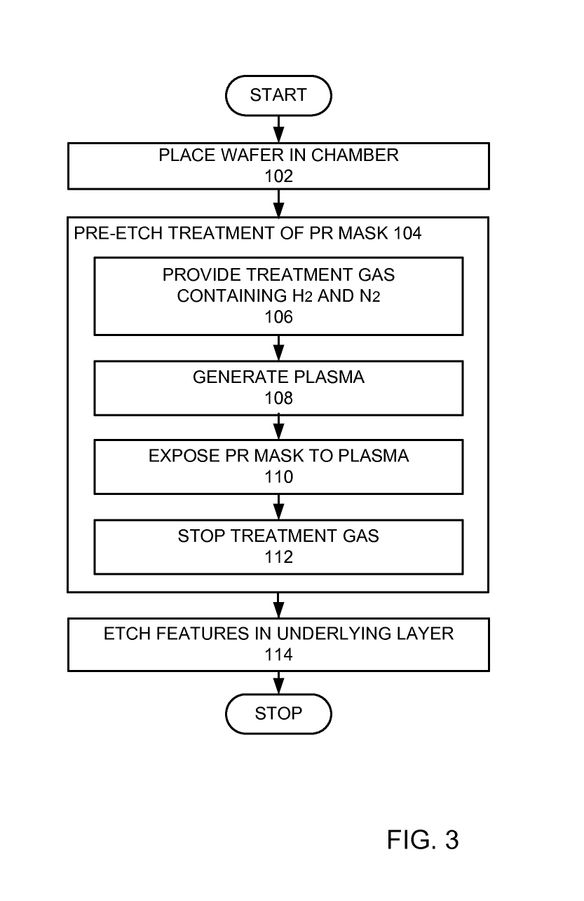

FIG. 3 is a process flow chart for a method that may be used in an embodiment of the present invention. The method reduces the LWR of line and space features in the patterned mask, and the resulting etch features as well, by a pre-plasma etch treatment of the PR mask. As shown in FIG. 3. a wafer stack having a patterned photoresist mask and an underlying layer is placed in a plasma chamber (step 102) and the pre-etch plasma treatment of the photoresist is conducted (step 104) prior to an etch process of the underlying layer. In the pre-etch plasma treatment, a treatment gas containing H₂ and N₂ is provided to the chamber (step 106), and a treatment plasma is generated from the treatment gas (step 108). After the patterned photoresist is exposed to the treatment plasma (step 110), the treatment gas is stopped (step 112). Then, features are etched into the underlying layer through the plasma-treated photoresist mask (step 114) using an appropriate etch gas or gases. The subsequent etch step 114 may include a BARC/DARC layer open process, a hard mask (ACL) open process, a dielectric etch process, and a conductor etch process. It should be noted that in the pre-etch plasma treatment (step 104) does not open or substantially etch the underlying layer exposed through the photoresist mask features. In other words, the etch rate of the underlying layer is not detectable or very slow and thus negligible.

A pre-etch plasma treatment of a photoresist material using H₂ has been known to reduce the LWR in a line-space pattern of the mask features. The use of hydrogen gas (H₂) is believed to cure the photoresist mask layer to provide a smoothened surface, as well as to generate a surface with more uniform etch resistant. The curing process by the H₂ component in the plasma reduces single and double C—O bonds from the surfaces of the photoresist mask (as a chemical reaction), such that the cured photoresist mask will sustain a more uniform edge deformation (i.e., less irregularities in the line edges) during the subsequent etch processes, yielding a better LWR. As a physical reaction, the photoresist mask shrinks as a result of the cure process.

Applicants have found that addition of N₂ to the treatment gas of H₂ further improves the LWR. Thus, in accordance with the embodiments of the present invention, the treatment gas further includes N₂ as an additive. The novel treatment gas of the H₂ and N₂ combination not only improves the LWR (especially high-frequency roughness) compared with the conventional H₂-only treatment gas, but also reduces the shrinkage of the photoresist material (i.e., increased CD). It is believed that the N₂ component in the pre-etch plasma treatment facilitates reflow of the photoresist material by reducing the glass transition temperature thereof. For example, the photoresist material may have the glass transition temperature of 100-110° C., but the reflow may occur about 40-45° C. The reflow smoothens the sidewalls of the patterned photoresist.

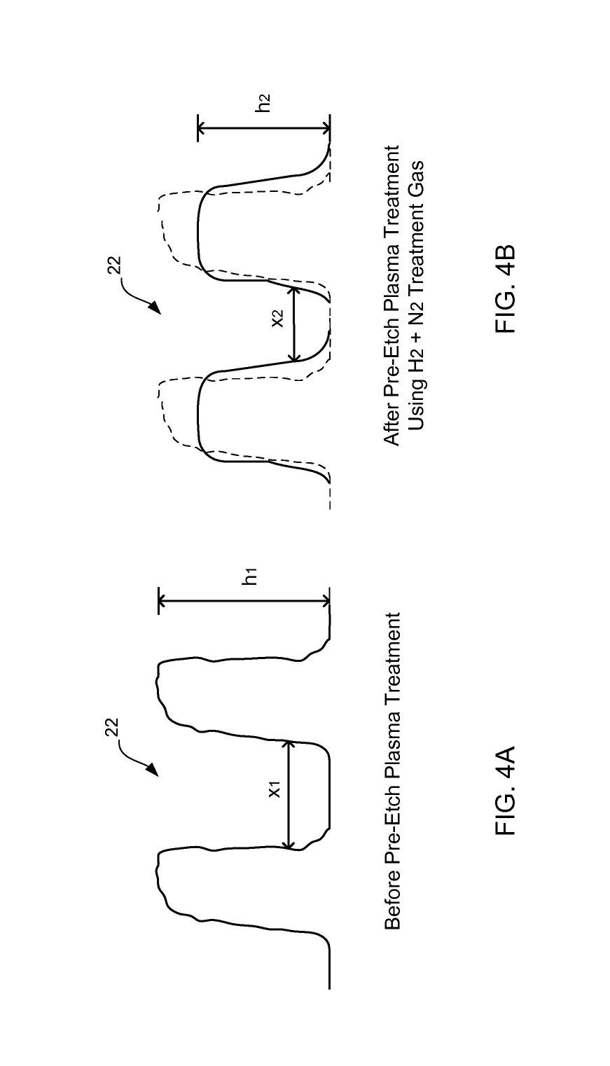

FIGS. 4A and 4B schematically illustrate a cross-sectional view of the photoresist pattern before and after the pre-etch plasma treatment (reflow) of the photoresist material, respectively, in accordance with one embodiment of the present invention. The space CD of the mask feature 22 is reduced from x1 (FIG. 4A) to x2 (FIG. 4B), while the height of the mask feature is also reduce from h1 (FIG>4A) to h2 (FIG. 4B) by the reflow of the photoresist material. The reflow also reduces the LWR of the mask feature 22. For example, it was observed that the LWR of 4.7 nm (prior to the pre-etch plasma treatment) was recued to 2.9 nm by treating the photoresist material using the treatment gas of H₂ and N₂, while the conventional H₂-only treatment reduced the LWR to 3.6 nm. However, it should be noted that these numbers are presented for illustrative purpose only, and are no way limiting. The flow ratio of N₂ with respect to H₂ in the treatment gas, as well as the pressure of the chamber and the power applied to the plasma, may be controlled so as to reduce the LWR of the mask feature.

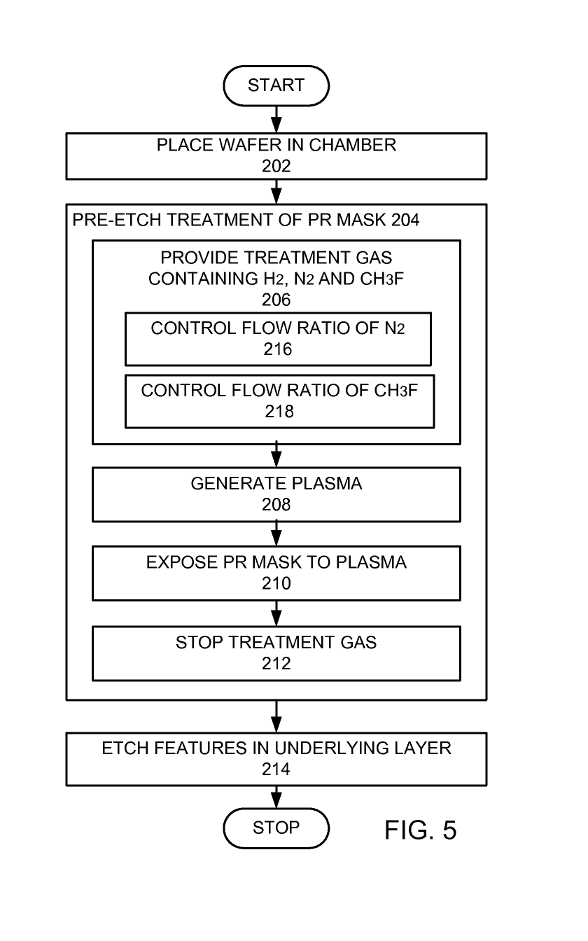

In accordance with another embodiment of the present invention, the treatment gas may further contain hydrofluorocarbon. The hydrofluorocarbon is preferably CH₃F (fluoromethane). However, other hydrofluorocarbons such as difluoroethane may be used. In accordance with this embodiment, the pre-etch plasma treatment of the photoresist material in reduces the space CD of the mask features, as well as the LWR of line and space features of the patterned mask (and in the resulting etch features). FIG. 5 is a process flow chart for a method that may be used in this embodiment. As shown in FIG. 5 similarly to the previous embodiment, the wafer stack having a patterned photoresist mask and an underlying layer (see FIG. 2, for example) is placed in a plasma chamber (step 202) and the pre-etch plasma treatment of the photoresist is conducted (step 204) prior to etching of the underlying layer. In the pre-etch plasma treatment (step 204), a treatment gas containing H₂, N₂, and a hydro fluorocarbon is provided to the chamber (step 206). In this example, CH₃F is used as the hydrofluorocarbon. A treatment plasma is generated from the treatment gas (step 208), and the patterned photoresist is exposed to the treatment plasma (step 210), and then the treatment gas is stopped (step 212). After the pre-etch plasma treatment, features are etched into the underlying layer through the plasma-treated photoresist mask (step 214) using an appropriate etch gas or gasses. The subsequent etch step 214 may include a BARC/DARC layer open process, a hard mask (ACL) open process, a dielectric etch process, a conductor etch process, and the like. It should be noted that in the pre-etch plasma treatment (step 204) does not open or substantially etch the underlying layer exposed through the photoresist mask features. In other words, the etch rate of the underlying layer is not detectable or very slow and thus negligible.

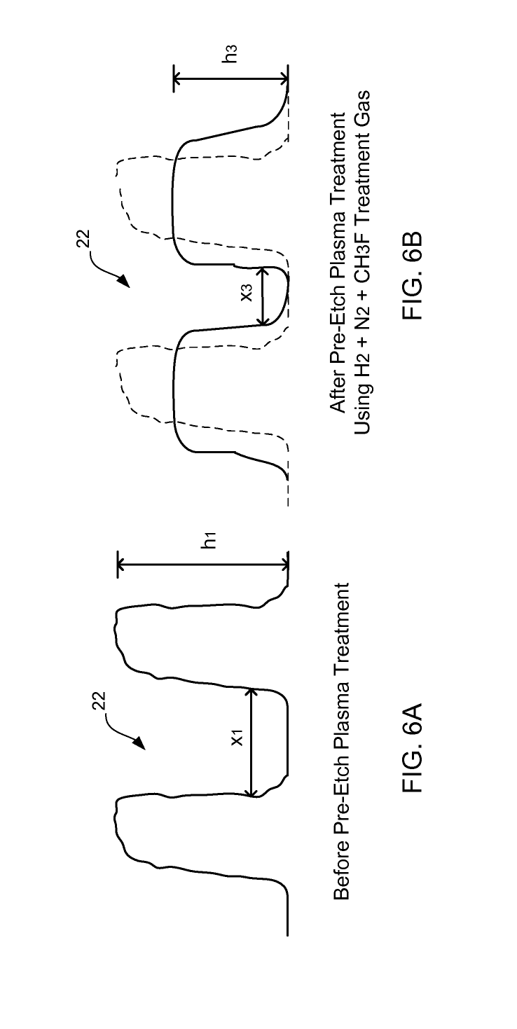

FIGS. 6A and 6B schematically illustrate a cross-sectional view of the photoresist pattern before and after the pre-etch plasma treatment (reflow +deposition) of the photoresist material, respectively, in accordance with one embodiment of the present invention. The space CD of the mask feature 22 is reduced from x1 (FIG. 6A) to x3 (FIG. 6B), while the height of the mask feature is also decreased from h1 (FIG. 6A) to h3 (FIG. 6B) by the pre-etch plasma treatment of the photoresist material. The reduced space CD according to this embodiment is substantially smaller than the reduced CD (x2) obtained in the previous embodiment using the treatment gas only containing H₂ and N₂. The space CD may be reduced by 15-20 nm. The pre-etch plasma treatment in this embodiment also reduces the LWR of the mask feature 22. For example, it was observed that the LWR of 4.7 nm (prior to the pre-etch plasma treatment) was recued to 3.2 nm by treating the photoresist material using the treatment gas of H₂, and N₂, and CH₃F, while the conventional H₂-only treatment reducing the LWR to 3.6 nm. However, it should be noted that these numbers are presented for illustrative purpose only, and are no way limiting.

As described above, exposing the photoresist material to the treatment plasma allows the photoresist mask to reflow so as to reduce the LWR of the mask features. The height of the mask features is also reduced by the reflow. The N₂ component of the treatment gas contribute to the reflow process. It is believed that exposing the photoresist material to the treatment plasma containing N₂ and hydrofluorocarbon also forms C—N based depositions on sidewalls of the photoresist mask so as to reduce the space CD of the mask features. The hydrofluorocarbon (CH₃F) component of the treatment gas contributes to the deposition during the treatment. Accordingly, the novel treatment gas containing H₂, N₂, and hydrofluorocarbon (for example, CH₃F) reduces the LWR and the height of the mask features, while forming C—N based depositions on sidewalls of the mask features in a single treatment step. The formation of the C—N based deposition also hardens the photoresist mask. It should be noted that, in a conventional pre-etch plasma treatment, an additional deposition step is necessary in the beginning so as to reduce the CD, which typically worsens the LWR of the mask features.

In addition, the subsequent etch process to form features in the underlying layer, it is observed that the pre-etch plasma treatment increases etch selectivity of the etchant to the underlying layer with respect to the photoresist mask. It is believed that the hardened photoresist mask is more durable and resisting to the etchant than a photoresist mask without the pre-etch plasma treatment. Thus, although the height of the photoresist mask is reduced by the pre-etch plasma treatment, the photoresist mask withstands the etch process.

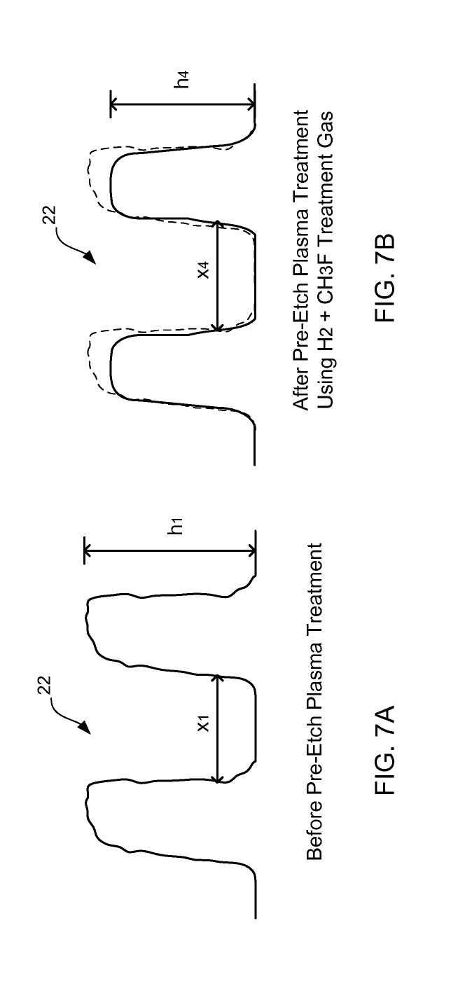

It should also be noted that adding CH₃F to a conventional H₂ treatment gas worsens the LWR while the space CD remains substantially the same. For comparison, FIGS. 7A and 7B schematically illustrate a cross-sectional view of the photoresist pattern before and after the pre-etch plasma treatment of the photoresist material, respectively, using the treatment gas of H₂ and CH₃F. As shown in FIGS. 7A and 7B, there is no significant change in the space CD of the mask feature 22 (x1˜x4) , while the height/shape of the mask feature 22 is slightly changed. It is believed that no or little reflow occurred in this pre-etch plasma treatment. With respect to the LWR, it was observed that the LWR of 4.7 nm (prior to the pre-etch plasma treatment) was slightly reduced to 4.4 nm by treating the photoresist material using the treatment gas of H₂ and CH₃F. However, since the conventional H₂-only treatment reduced the LWR to 3.6 nm, for example, adding CH₃F to H₂ actually worsened the LWR with no meaningful reduction of the space CD. (It should be noted that these numbers are presented for illustrative purpose only, and are no way limiting.) Thus, compared with the conventional H₂ treatment gas, the CH₃F additive showed no or little advantages. However, if CH₃F is added to the pre-etch plasma treatment gas of H₂ +N₂, as described above, the LWR and the space CD are both reduced. This is a very unexpected result of the novel component gas combination of the pre-etch plasma treatment in the present invention.

Referring back to FIG. 5, in accordance with an embodiment of the present invention, when the treatment gas is provided (step 206), the flow ratio of N₂ with respect to H₂ is controlled (step 216) such that the exposing the photoresist material to the plasma (step 208) reduces the LWR of the mask features. In addition, the flow ratio of CH₃F with respect to H₂ is also controlled (step 218) such that the exposing (step 208) reduces the space CD of the mask features. In general, as the flow ratio of CH₃F increases, the space CD is reduced. The pressure of the chamber and the power supplied to the plasma may also be controlled to achieve a suitable combination of the reduction of the space CD and the LWR.

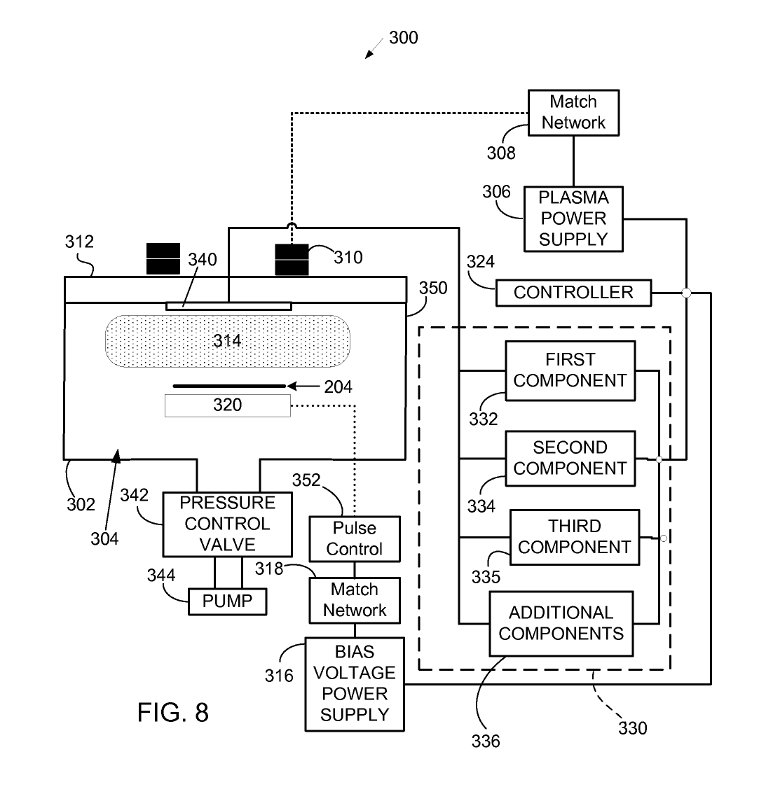

FIG. 8 schematically illustrates an example of a plasma processing system 300 which may be used in one embodiment of the present invention. The plasma processing system 300 includes a plasma reactor 302 having a plasma processing chamber 304 therein defined by a chamber wall 350. A plasma power supply 306, tuned by a match network 308, supplies power to a TCP coil 310 located near a power window 312 to be an electrode that provides power to the plasma processing chamber 304 to create a plasma 314 in the plasma processing chamber 304. The TCP coil (upper power source) 310 may be configured to produce a uniform diffusion profile within processing chamber 304. For example, the TCP coil 310 may be configured to generate a toroidal power distribution in the plasma 314. The power window 312 is provided to separate the TCP coil 310 from the plasma chamber 304 while allowing energy to pass from the TCP coil 310 to the plasma chamber 304. A wafer bias voltage power supply 316 tuned by a match network 318 provides power to an electrode 320 to set the bias voltage on the silicon substrate 204 which is supported by the electrode 320, so that the electrode 320 in this embodiment is also a substrate support. A pulse controller 352 causes the bias voltage to be pulsed. The pulse controller 352 may be between the match network 318 and the substrate support or between the bias voltage power supply 316 and the match network 318 or between the controller 324 and the bias voltage power supply 316 or in some other configuration to cause the bias voltage to be pulsed. A controller 324 sets points for the plasma power supply 306 and the wafer bias voltage supply 316.

The plasma power supply 306 and the wafer bias voltage power supply 316 may be configured to operate at specific radio frequencies such as, for example, 13.56 MHz, 27 MHz, 2 MHz, 400 kHz, or combinations thereof. Plasma power supply 306 and wafer bias power supply 316 may be appropriately sized to supply a range of powers in order to achieve desired process performance. For example, in one embodiment of the present invention, the plasma power supply 306 may supply the power in a range of 100 to 10000 Watts, and the wafer bias voltage power supply 316 may supply a bias voltage in a range of 10 to 2000 V. In addition, the TCP coil 310 and/or the electrode 320 may be comprised of two or more sub-coils or sub-electrodes, which may be powered by a single power supply or powered by multiple power supplies.

As shown in FIG. 8, the plasma processing system 300 further includes a gas source/gas supply mechanism 330. The gas source includes a first component gas source 332, a second component gas source 334, and a third component gas source 335, and optionally additional component gas sources 336. The first, second, and third component gases may be H₂, N₂, and CH₃F, respectively, as discussed above. The optional component gas may be an etchant gas(ses) for etching the underlying layer(s). The gas sources 332, 334, 335, and 336 are in fluid connection with processing chamber 304 through a gas inlet 340. The gas inlet may be located in any advantageous location in chamber 304, and may take any form for injecting gas. Preferably, however, the gas inlet may be configured to produce a “tunable” gas injection profile, which allows independent adjustment of the respective flow of the gases to multiple zones in the process chamber 304. The process gases and byproducts are removed from the chamber 304 via a pressure control valve 342, which is a pressure regulator, and a pump 344, which also serves to maintain a particular pressure within the plasma processing chamber 304 and also provides a gas outlet. The gas source/gas supply mechanism 330 is controlled by the controller 324. A Kiyo system by Lam Research Corporation may be used to practice an embodiment of the invention.

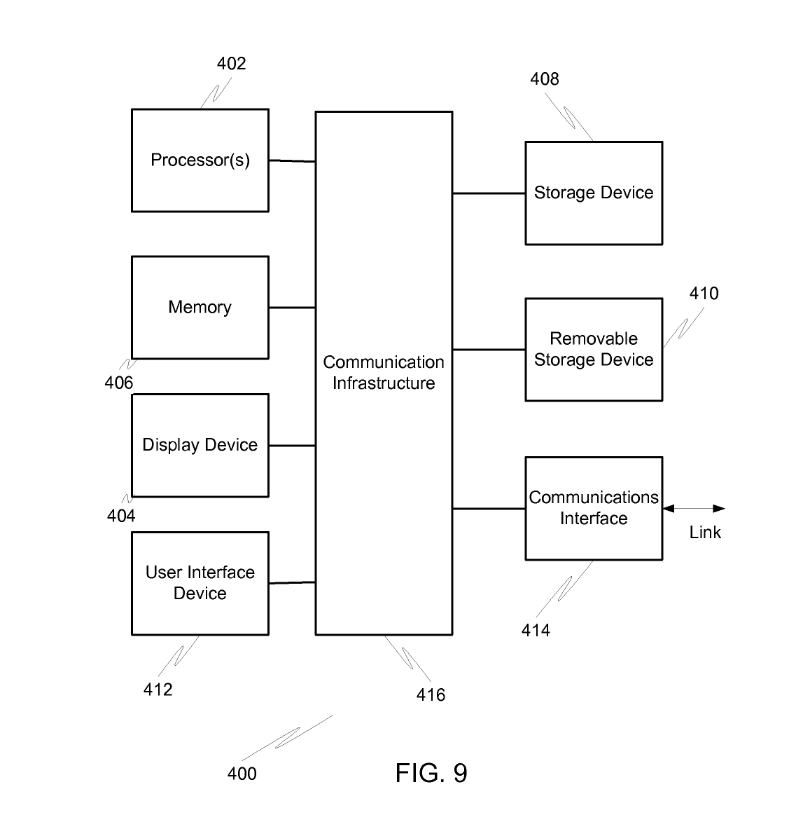

FIG. 9 is a high level block diagram showing a computer system 400, which is suitable for implementing a controller 324 used in embodiments of the present invention.

The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

### EXAMPLES

In the pre-etch plasma treatment in the first embodiment (step 106 as described above), the treatment gas containing H₂ and N₂ is provided into the process chamber (confined plasma volume 340) from the gas source 330. The treatment gas has a flow rate, and the flow ratio of component gases H₂ and N₂ is controlled so as to reduce the LWR. For example, the flow ratio of H₂ and N₂ (H₂:N₂) may be between 2:1 and 10:1. Preferably, the flow ratio of H₂ and N₂ is between 3:1 and 7:1. More preferably, the flow ratio of H₂ and N₂ is about 4:1. For example, the flow rate of H₂ may be 200 sccm, and that of N₂ may be adjusted with respect to H₂ according to the desired flow ratio, for example, at 50 sccm.

In the pre-etch plasma treatment in the second embodiment (step 206 as described above), the treatment gas containing H₂, N₂ , and CH₃F is provided into the process chamber (confined plasma volume 340) from the gas source 330. The flow ratio of N₂ with respect to H₂ is controlled (step 216) such that the pre-etch plasma treatment of the photoresist material (step 210) reduces the LWR of the mask features. The flow ratio of CH₃F with respect to H₂ is also controlled (step 218) such that the pre-etch plasma treatment (step 210) reduces a space critical dimension (CD) of the mask features. For example, the flow ratio of H₂ and N₂ (H₂: N₂) may be between 2:1 and 10:1. Preferably, the flow ratio of H₂ and N₂ is between 3:1 and 7:1. More preferably, the flow ratio of H₂ and N₂ is about 4:1. For example, the flow rate H₂ may be 200 sccm, and that of N₂ may be adjusted with respect to H₂, for example, at 50 sccm. The flow ratio of H₂ and hydrofluorocarbon (H₂:CH₃F) may be between 10:1 and 100:1. Preferably, the flow ratio of H₂ and CH₃F is between 10:1 and 60:1. More preferably, the flow ratio of H₂ and CH₃F is between 10:1 and 40:1. For example, the flow rate of H₂, N₂, and CH₃F may be 200 sccm, 50 sccm, and 5 sccm, respectively. The flow rate of CH₃F may be increased, for example, in a range between 5 sccm to 15 sccm when that of H₂ and CH₃F are set at 200 sccm and 50 sccm, respectively. The flow ratio of both of N₂ and CH₃F can be changed with respect to the fixed flow ratio of H₂. In general, as the flow ratio of CH₃F increases, the space CD is reduced. The pressure of the chamber may be in a range between 1 mT to 20 mT, preferably, between 5 mT and 15 mT, or about 10 mT. The power can also be adjusted to achieve a suitable combination of the reduction of the space CD and the LWR. For example, the TCP power may be in a range between 600 W and 1800 W to achieve both of the reduction of the space CD and the LWR. The TCP power may be about 900W.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for forming features through a photoresist mask into an underlying layer, the photoresist mask having patterned mask features, the method comprising:
providing a treatment gas containing H₂ and N₂;
generating a plasma from the treatment gas;
exposing the photoresist mask to the plasma;
stopping the treatment gas; and
etching the features into the underlying layer through the plasma-treated photoresist mask.

2. The method of claim 1, wherein the treatment gas further contains hydrofluorocarbon.

3. The method of claim 1, wherein the hydrofluorocarbon is CH₃F.

4. The method of claim 1, wherein the mask features include a line pattern, the method further comprising:
controlling a flow ratio of N₂ with respect to H₂ in the treatment gas such that the exposing reduces line width roughness (LWR) of the mask features.

5. The method of claim 4, the flow ratio of H₂ and N₂ (H₂:N₂) is between 2:1 and 10:1.

6. The method of claim 3, the mask features include a line pattern, the method further comprising:
controlling a flow ratio of CH₃F with respect to H₂ in the treatment gas such that the exposing reduces a space critical dimension (CD) of the mask features.

7. The method of claim 6, a flow ratio of H₂ and hydrofluorocarbon (H₂:CH₃F) is between 10:1 and 100:1.

8. The method of claim 1, wherein the mask features include a line pattern, and the exposing allows the photoresist mask to reflow and reduces a height of the mask features.

9. The method of claim 8, the exposing reduces line width roughness (LWR) of the mask features.

10. The method of claim 2, wherein the exposing forms C—N based depositions on sidewalls of the mask features.

11. The method of claim 10, wherein the exposing hardens the photoresist mask so as to increase resistance to an etchant of the underlying layer during the forming features.

12. A method forming features through a photoresist mask into an underlying layer, the photoresist mask including patterned mask features having a line width roughness (LWR) and a space critical dimension (CD), the method comprising:
providing a treatment gas containing H₂, N₂, and CH₃F;
generating a plasma from the treatment gas;
exposing the photoresist mask to the plasma, wherein the exposing reduces both of the LWR and the CD of the mask features;
stopping the treatment gas; and
etching the features into the underlying layer through the plasma-treated photoresist mask.

13. The method of claim 12, wherein the exposing allows the photoresist mask to reflow so as to reduce line width roughness (LWR) and a height of the mask features, while forming C—N based depositions on sidewalls of the mask features.

14. The method of claim 12, wherein the exposing increases selectivity to the underlying layer with respect to the photoresist mask during the forming features.

15. An apparatus for forming features through a patterned photoresist mask into an underlying layer, said apparatus comprising:
a plasma processing chamber, comprising:
a chamber wall forming a plasma processing chamber enclosure;
a chuck for supporting and chucking a substrate within the plasma processing chamber enclosure;
a pressure regulator for regulating the pressure in the plasma processing chamber enclosure;
at least one electrode or coil for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising:
a treatment gas source, including an H₂ gas source, an N₂ source, and an optional hydrofluorocarbon gas source; and
a feature-forming gas source;
a controller controllably connected to the gas source, the chuck, and the at least one electrode or coil, comprising:
at least one processor; and
non-transient computer readable media, comprising:
computer readable code for treating the photoresist mask disposed over the underlying layer, comprising:
computer readable code providing a treatment gas containing H₂, N₂, and optional hydrofluorocarbon;
computer readable code for forming a plasma from the treatment gas;
computer readable code for exposing the photoresist mask to the plasma, wherein the exposing reduces both of line width roughness (LWR) and critical dimension (CD) of the mask features; and
computer readable code for stopping the treatment gas; and
computer readable code for forming the features into the underlying layer through the plasma-treated photoresist mask.
